(19) United States
(12) Patent Application Publication
(10) Pub. No.: US 2007/0059610 A1
(43) Pub. Date: Mar. 15, 2007

(54) Method of making and designing dummy patterns for semiconductor devices and semiconductor devices having dummy patterns

(75) Inventors: Sang-Moo Jeong, Suwon-si (KR); Sun-Hoo Park, Yongin-si (KR); Dong-Hyun Han, Gunpo-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/414,700

(22) Filed: Apr. 28, 2006

(30) Foreign Application Priority Data
Sep. 12, 2005 (KR) 10-2005-0084859

(51) Int. Cl. G03F 1/00

(52) U.S. Cl. 430/5

(57) ABSTRACT

A semiconductor device with dummy patterns and methods of designing and making dummy patterns of a semiconductor device are provided. The method includes forming a first layout having main patterns, adding dot dummy patterns to the first layout to generate a second layout, and adding linked line/space dummy patterns to the second layout to generate a third layout. The dot dummy patterns may be oblique dot dummy patterns.

### CROSS-REFERENCE TO RELATED APPLICATION

This application claims the benefit of Korean Patent Application No. 2005-0084859, filed Sep. 12, 2005, the contents of which are hereby incorporated herein by reference in their entirety.

### BACKGROUND OF THE INVENTION

1. Field of the Invention

The present invention relates to a semiconductor device, and more particularly, to a method of designing dummy patterns for a semiconductor device.

2. Description of the Related Art

As semiconductor devices become more highly integrated, conductive pattern multi-layering technology becomes more important. A method of sequentially stacking a conductive pattern and an interlayer dielectric on a semiconductor substrate is widely used for the multi-layering technology. However, multi-layering of the conductive pattern and the interlayer dielectric results in surface unevenness. Surface unevenness in a lower layer may distort a pattern formed in an upper layer. For example, surface unevenness of a lower layer may distort a pattern applied in a photolithography process for forming an upper interconnection, and/or may distort step coverage in a subsequent deposition process. Accordingly, techniques of planarizing a stacked conductive pattern and interlayer dielectric have been researched.

FIG. 1 is a cross-sectional view illustrating a portion of a conventional semiconductor device.

Referring to FIG. 1, an interlayer dielectric 13 is formed on a semiconductor substrate 11. The semiconductor substrate 11 may be divided into a cell region C and a peripheral circuit region P. Grooves in parallel with each other are formed within the interlayer dielectric 13 of the cell region C. A metal layer is formed to fill the grooves and cover the semiconductor substrate 11. The metal layer is planarized to form metal interconnections 15 within the grooves. A chemical mechanical polishing (CMP) process employing the interlayer dielectric 13 as a stop layer is widely used to planarize the metal layer.

The interlayer dielectric 13 is usually formed of a silicon oxide layer. The metal layer is usually formed of a copper (Cu) layer. The Cu layer and the silicon oxide layer have different hardness and chemical reaction properties. In general, the Cu layer has a lower hardness than the silicon oxide layer. However, the grooves filled with the Cu layer are formed in the cell region C. That is, the cell region C has a higher pattern density than the peripheral circuit region P. Here, the pattern density may be defined as the ratio of the area of the metal interconnections 15 to the area of the cell region C. In this case, the cell region C is polished faster than the peripheral circuit region P by the CMP process. As a result, a surface step E occurs between the top surface of the cell region C and the top surface of the peripheral circuit region P.

The surface step E distorts pattern formation of a subsequent process. In order to minimize the surface step E, it is advantageous for the peripheral circuit region P and the cell region C to have similar pattern densities. That is, when the pattern density of the peripheral circuit region P is close to that of the cell region C, the interlayer dielectric 13 and the metal interconnections 15 can have excellent planarization properties. Accordingly, a method of additionally disposing dummy patterns in the peripheral circuit region P has been researched.

A method of forming dummy patterns is disclosed in U.S. Patent Publication No. 2003/0204832 A1 entitled “Automatic Generation Method of Dummy Patterns,” to Matumoto.

According to Matumoto, dummy pattern components including regularly arranged dummy patterns are prepared. Mask pattern data are used to set a dummy prohibition region in a layout. The dummy pattern components are overlaid on the layout so that any dummy pattern components which overlap the dummy prohibition region are eliminated.

Another method of forming the dummy patterns is disclosed in U.S. Patent Publication No. 2005/051809 A1 entitled “Dummy Fill for Integrated Circuits,” to Smith et al.

The layout of the semiconductor device may include regions where the dummy patterns are difficult to form. In this case, a method is known of generating a layout by repeatedly overlaying the dummy patterns on the layout while changing the sizes and coordinates of the dummy patterns. However, this method requires a system with enormous capacity and takes an exceedingly long time for designing the dummy patterns.

### SUMMARY OF THE INVENTION

An embodiment of the invention provides a method of designing dummy patterns of a semiconductor device having an excellent planarization property while simplifying the design process.

Another embodiment of the invention provides a semiconductor device having dummy patterns.

In one aspect, the invention is directed to A method of designing dummy patterns. The method includes forming a first layout having main patterns. Dot dummy patterns are added to the first layout to generate a second layout. Linked line/space dummy patterns are added to the second layout to generate a third layout.

In some embodiments of the present invention, the dot dummy patterns may have oblique dot dummy patterns. The oblique dot dummy patterns may be generated by arranging rectangular or circular dots in an oblique direction.

In other embodiments, generating the second layout may include setting dummy prohibition regions in the first layout. The dummy prohibition regions may be set by enlarging the main patterns by a first distance in the first layout. The first distance is preferably set to be higher than a resolution limit of a photolithography process. A dummy layout having the dot dummy patterns may be formed. The dummy layout may be overlaid onto the first layout, and dot dummy patterns of the overlaid dummy layout at least partially overlapping any of the dummy prohibition regions may be eliminated.

In still other embodiments, the linked line/space dummy patterns may be composed of links of dummy lines and dummy spaces, and the dummy line may have a bar shape, an elliptical shape, or a combined bar shape and elliptical shape.

In yet other embodiments, generating the third layout may include determining dummy regions in the second layout. A linked line/space dummy rule may be provided. The linked line/space dummy patterns may be generated in the dummy regions of the second layout based on the linked line/space dummy rule. The dummy regions may be spaced apart from the main patterns by a first distance and spaced apart from the dot dummy patterns by a second distance. The first and second distances preferably have values higher than a resolution limit of a photolithography process.

In yet other embodiments, the linked line/space dummy rule may include a dummy line rule and a dummy space rule. The dummy line rule may include a minimum length, a minimum width, a maximum length, and a maximum width of a dummy line. The minimum length and the minimum width of the dummy line preferably have values higher than a resolution limit of a photolithography process. The dummy space rule may include a minimum length, a minimum width, a maximum length, and a maximum width of a dummy space. The minimum length and the minimum width of the dummy space preferably have values higher than a resolution limit of a photolithography process.

In another aspect, the invention is directed to another method of designing dummy patterns. The method includes forming a first layout having main patterns. Dot dummy patterns are added to the first layout to generate a second layout. The dot dummy patterns have rectangular or circular dots. Dummy regions are determined in the second layout. The dots are added to the dummy regions of the second layout such that an inter-dot spacing is larger than a resolution limit of a photolithography process to generate a third layout.

In some embodiments of the present invention, the dot dummy patterns may have oblique dot dummy patterns. The oblique dot dummy patterns may be generated by arranging the rectangular or circular dots in an oblique direction.

In other embodiments, generating the second layout may include setting dummy prohibition regions in the first layout. The dummy prohibition regions may be set by enlarging the main patterns by a first distance in the first layout. The first distance preferably has a value set to be higher than a resolution limit of a photolithography process. A dummy layout having the dot dummy patterns may be provided. The dummy layout may be overlaid onto the first layout, and dot dummy patterns of the overlaid dummy layout at least partially overlapping any of the dummy prohibition regions may be eliminated.

In one embodiment, the dummy regions are spaced apart from the main patterns by a first distance and spaced apart from the dot dummy patterns by a second distance, the first and second distances having values higher than a resolution limit of a photolithography process.

In still another aspect, the invention is directed to a semiconductor device having dummy patterns. The semiconductor device includes a substrate and main patterns formed on the substrate. Dot dummy patterns are disposed between the main patterns on the substrate. Linked line/space dummy patterns are disposed between the main patterns on the substrate.

In some embodiments of the present invention, the dot dummy patterns may have oblique dot dummy patterns. The oblique dot dummy patterns may be rectangular or circular dots arranged in an oblique direction. The oblique dot dummy patterns may be spaced apart from the main patterns by a first distance. The first distance preferably has a value set to be higher than a resolution limit of a photolithography process. The dots may be spaced apart from each other by a second distance. The second distance preferably has a value set to be higher than a resolution limit of a photolithography process.

In other embodiments, the linked line/space dummy patterns may include links of dummy lines and dummy spaces. The dummy line may have a bar shape, an elliptical shape, or a combined bar shape and elliptical shape. The linked line/space dummy patterns may be spaced apart from the main patterns by a first distance and spaced apart from the dot dummy patterns by a second distance. The first and second distances preferably have values higher than a resolution limit of a photolithography process.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a cross-sectional view illustrating a portion of a conventional semiconductor device.

FIGS. 2 to 7 are plan views illustrating methods of designing and making dummy patterns of a semiconductor device in accordance with an embodiment of the present invention.

FIG. 8 is a cross-sectional view taken along line I-I′ of FIG. 7 illustrating the semiconductor device in accordance with an embodiment of the present invention.

FIG. 9 is a plan view illustrating a method of designing and making dummy patterns of a semiconductor device in accordance with another embodiment of the present invention.

### DETAILED DESCRIPTION OF THE INVENTION

The present invention will now be described more fully hereinafter with reference to the accompanying drawings, in which preferred embodiments of the invention are shown. When a layer is described as being formed on another layer or on a substrate, the layer may be formed on the other layer or on the substrate, or a third layer may be interposed between the layer and the other layer or the substrate.

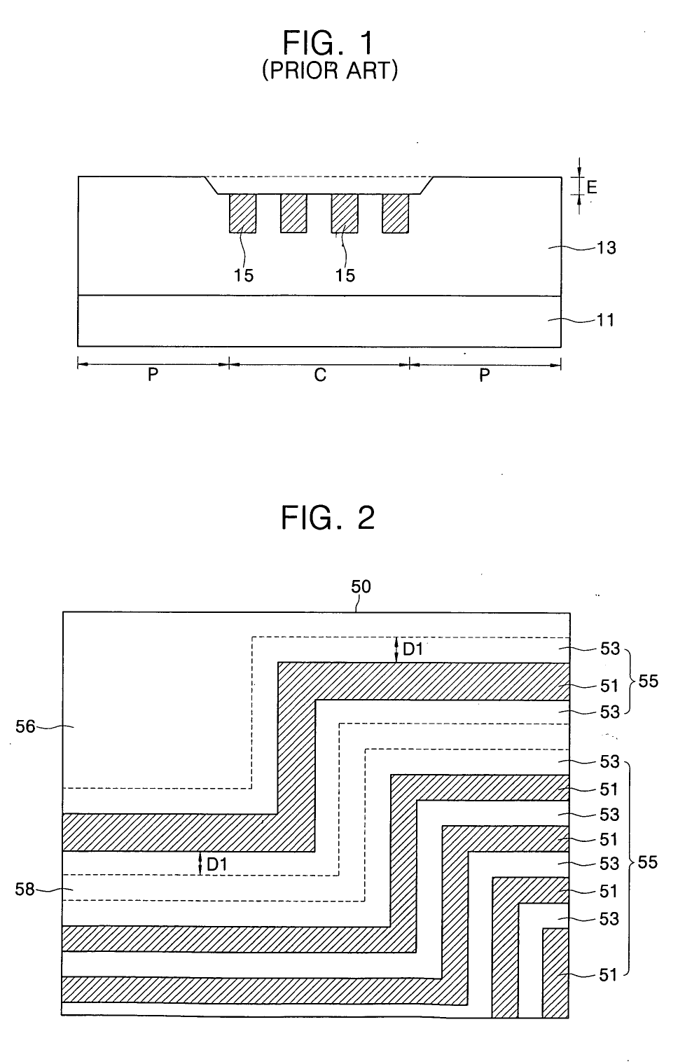

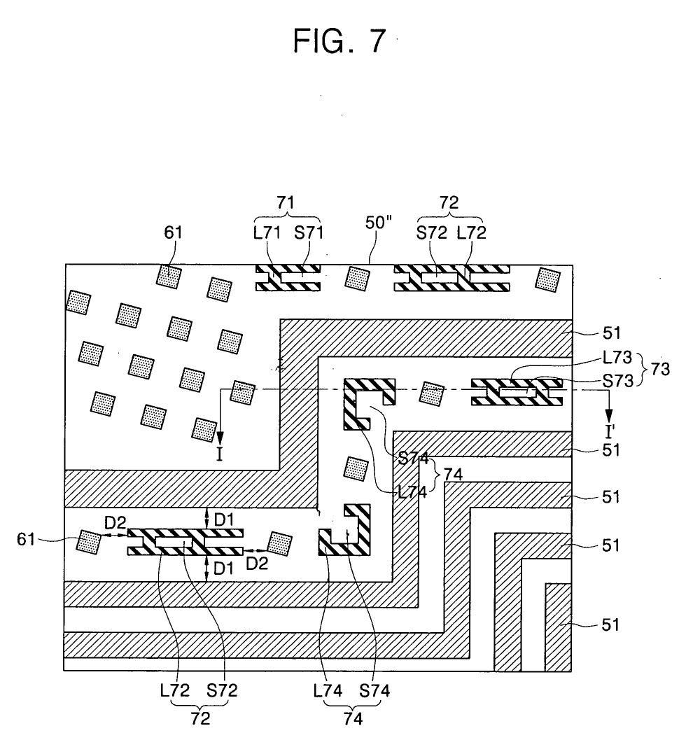

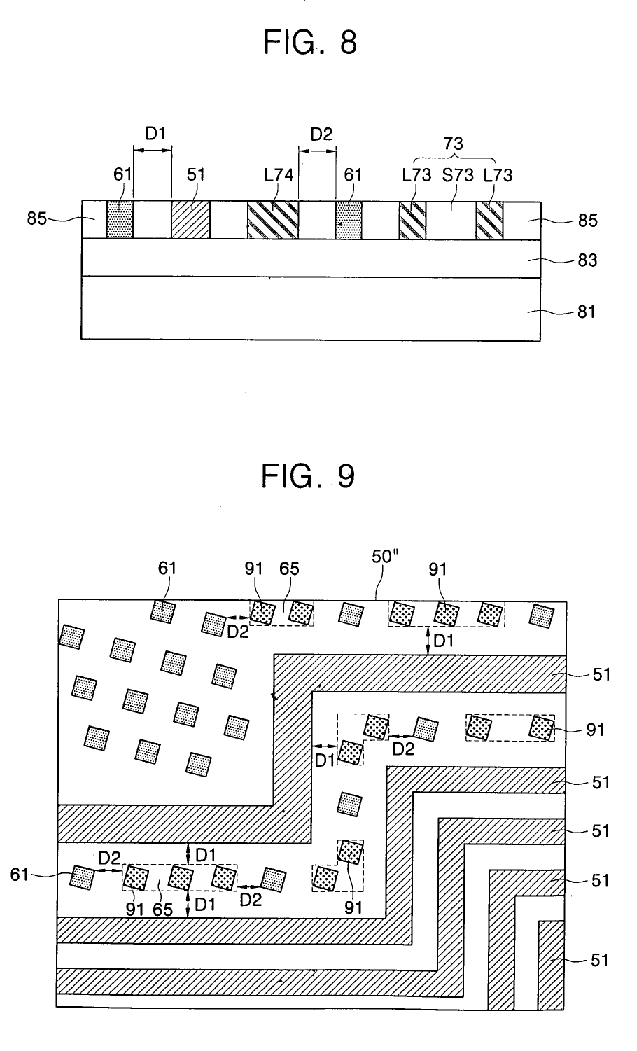

FIGS. 2 to 7 are plan views illustrating methods of designing and making dummy patterns of a semiconductor device in accordance with an embodiment of the present invention, FIG. 8 is a cross-sectional view taken along line I-I′ of FIG. 7 illustrating the semiconductor device in accordance with an embodiment of the present invention, and FIG. 9 is a plan view illustrating a method of designing and making dummy patterns of a semiconductor device in accordance with another embodiment of the present invention.

First, methods of designing and making dummy patterns of a semiconductor device in accordance with an embodiment of the present invention will be described with reference to FIGS. 2 to 7.

Referring to FIG. 2, a first layout 50 having main patterns 51 is provided.

The main patterns 51 may be conductive patterns or insulating patterns. That is, the main patterns 51 required for the configuration of the semiconductor device are provided in the first layout 50. The main patterns 51 may have line shapes parallel to one another, plate shapes, or combined line and plate shapes. In addition, the main patterns 51 may have different lengths and widths from one another.

Each of the main patterns 51 may extend by a first distance D1 to set dummy prohibition regions 55 within the first layout 50. In this case, the dummy prohibition regions 55 include the main patterns 51 and regions 53 extended from the main patterns 51. As a result, a first dummy region 56 and a second dummy region 58 may be defined within the first layout 50. That is, the first and second dummy regions 56 and 58 may be defined as regions different from the dummy prohibition regions 55 within the first layout 50. In addition, the first dummy region 56 may be a relatively larger region than the second dummy region 58. The second dummy region 58 may be relatively smaller than the first dummy region 56.

The first distance D1 is preferably set to a value higher than the resolution limit of a photolithography process. In addition, when the main patterns 51 are the conductive patterns, the first distance D1 may be set in consideration of electrical characteristics of the main patterns 51. For example, the main patterns 51 may be metal interconnections such as copper (Cu). In this case, a coupling capacitance is formed between the main patterns 51.

The coupling capacitance affects the transmission speed of an electrical signal delivered via the main patterns 51. That is, when the coupling capacitance increases, the transmission speed of the electrical signal may decrease due to RC delay. The decrease in transmission speed of the electrical signal causes an operating speed of the semiconductor device to decrease. Accordingly, it is advantageous to decrease the coupling capacitance as much as possible in order to enhance the operating speed of the semiconductor device. The magnitude of the coupling capacitance is in inverse proportion to the distance between the main patterns 51. That is, the magnitude of the coupling capacitance decreases when the distance between the main patterns 51 increases, whereas the magnitude of the coupling capacitance increases when the distance between the main patterns 51 decreases. Accordingly, the first distance D1 may be set in consideration of the coupling capacitance. In addition, regions where the main patterns 51 are spaced apart by less than the first distance D1 may be collectively set as the dummy prohibition region 55.

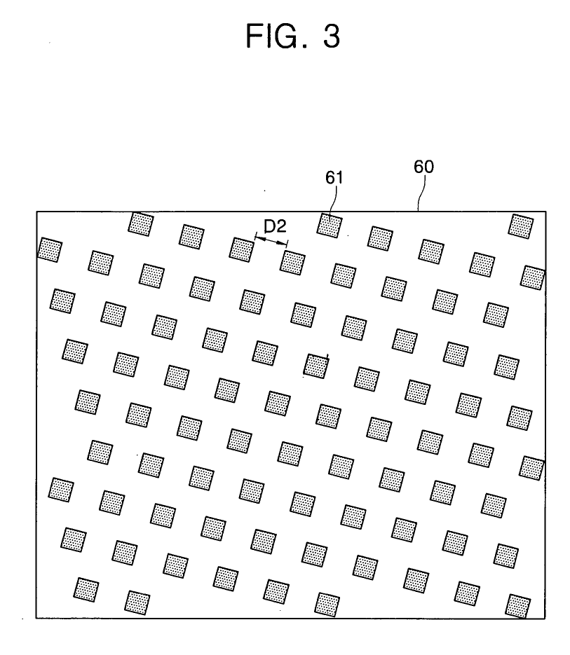

Referring to FIG. 3, a dummy layout 60 having dot dummy patterns 61 is provided.

The dummy layout 60 may have the dot dummy patterns 61 which are regularly arranged. The dot dummy patterns 61 may be formed by arranging rectangular or circular dots in an oblique direction. In this case, the dot dummy patterns 61 may be defined as oblique dot dummy patterns. Alternatively, the dot dummy patterns 61 may be formed by arranging rectangular or circular dots in a vertical or horizontal direction. In this case, the dot dummy patterns 61 may be defined as symmetric dot dummy patterns.

The dot dummy patterns 61 may be spaced apart from each other by a second distance D2. Sizes of the dot dummy patterns 61 and the second distance D2 are preferably set to be higher than the resolution limit of a photolithography process. In addition, the dot dummy patterns 61 may be set in consideration of the pattern density of the dummy prohibition regions 55. The pattern density may be defined as the ratio of the area of the main patterns 51 to the area of the dummy prohibition regions 55. Similarly, the ratio of the area of the dot dummy patterns 61 to the area of the dummy layout 60 may be defined as the dummy density. For example, the sizes of the dot dummy patterns 61 and the second distance D2 may be set to allow the dummy density and the pattern density to have the same value. The dot dummy patterns 61 may be material patterns of the same kind as the main patterns 51. That is, the dot dummy patterns 61 may be conductive patterns or insulating patterns.

When the dot dummy patterns 61 are conductive patterns, a coupling capacitance may be formed between the dot dummy patterns 61 and the main patterns 51. In this case, the first distance D1 and the second distance D2 may be set in consideration of the electrical characteristics of the dot dummy patterns 61 and the main patterns 51. In addition, the dot dummy patterns 61 have a relatively lower coupling capacitance than the plate dummy pattern.

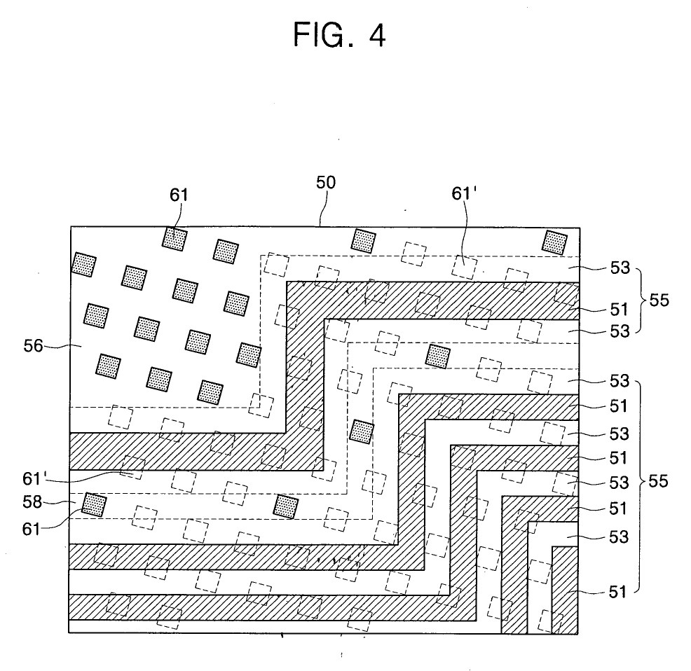

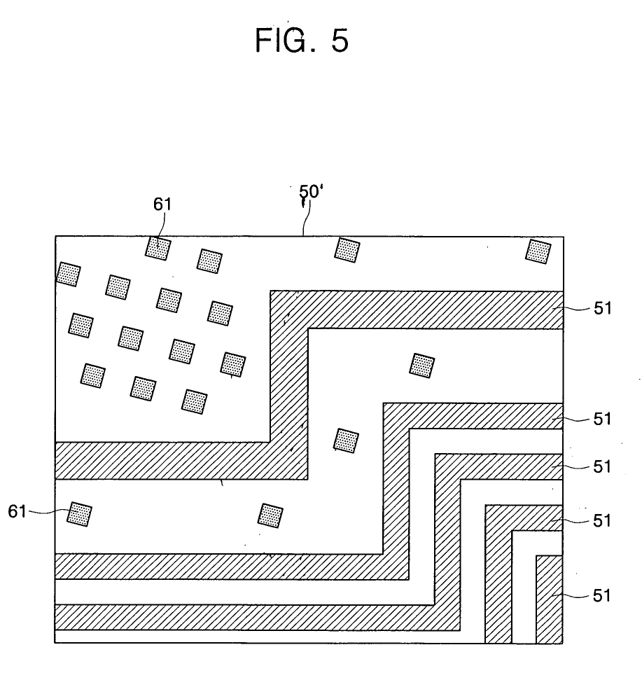

Referring to FIGS. 4 and 5, the dummy layout 60 is overlaid onto the first layout 50. As a result, dot dummy patterns 61′ that at least partially overlap the dummy prohibition regions 55 may be sorted out. Subsequently, the dot dummy patterns 61′ that at least partially overlap the dummy prohibition regions 55 are eliminated to generate a second layout 50′. Consequently, the main patterns 51 and the dot dummy patterns 61 added between the main patterns 51 may coexist within the second layout 50′. In this case, the dot dummy patterns 61 may remain within the first and second dummy regions 56 and 58.

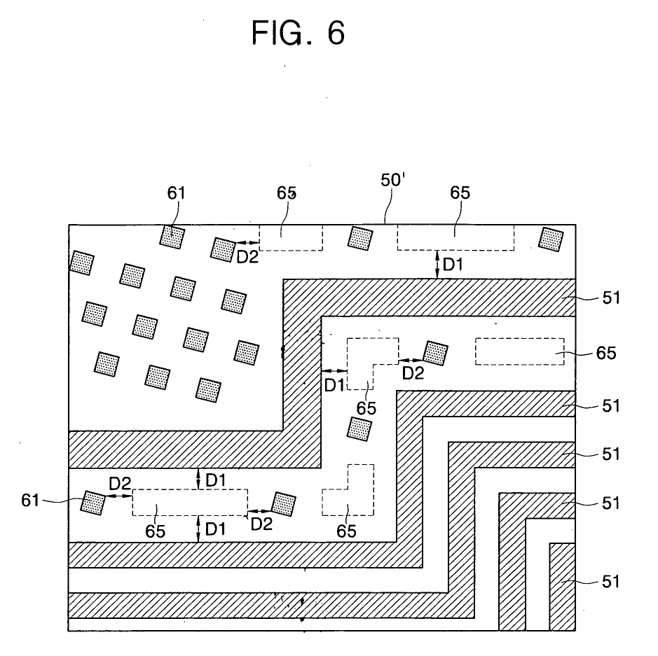

Referring to FIG. 6, third dummy regions 65 are determined in the second layout 50′.

The dummy layout 60 has the dot dummy patterns 61 which are regularly arranged. While the second layout 50′ is generated, the dot dummy patterns 61′ that at least partially overlap the dummy prohibition regions 55 are eliminated. Accordingly, spaces where the dot dummy patterns 61′ are eliminated are formed within the first and second dummy regions 56 and 58. The third dummy regions 65 may be set in spaces exceeding the resolution limit of the photolithography process among the spaces where the dot dummy patterns 61′ are eliminated. In addition, the third dummy regions 65 may be set to be spaced apart from the main patterns 51 by the first distance D1 and to be spaced apart from the dot dummy patterns 61 by the second distance D2. As shown in the drawing, the third dummy regions 65 may have bar shapes or combined-bar shapes.

Referring to FIG. 7, linked line/space dummy patterns 71, 72, 73, and 74 are added to the second layout 50′ to generate a third layout 50″.

Specifically, a linked line/space dummy rule is provided. The linked line/space dummy patterns 71, 72, 73, and 74 may be formed within the third dummy regions 65 by linking dummy lines L71, L72, L73, and L74 and dummy spaces S71, S72, S73, and S74, respectively, according to the linked line/space dummy rule. The dummy lines L71, L72, L73, and L74 may have bar shapes, elliptical shapes, or combined bar and elliptical shapes. The linked line/space dummy rule may have a dummy line rule and a dummy space rule. The dummy line rule may include minimum and maximum lengths and widths of the dummy lines L71, L72, L73, and L74. The minimum length and width of the dummy lines L71, L72, L73, and L74 are preferably set to be higher than the resolution limit of the photolithography process. In addition, the dummy space rule may include the minimum and maximum lengths and widths of the dummy spaces S71, S72, S73, and S74. The minimum length and width of the dummy spaces S71, S72, S73, and S74 are preferably set to be higher than the resolution limit of the photolithography process. The linked line/space dummy patterns 71, 72, 73, and 74 may be set to be spaced apart from the main patterns 51 by the first distance D1 and to be spaced apart from the dot dummy patterns 61 by the second distance D2.

In addition, the linked line/space dummy patterns 71, 72, 73, and 74 may be set in consideration of the pattern density of the dummy prohibition regions 55. For example, the linked line/space dummy patterns 71, 72, 73, and 74 may be formed by various links of the first to fourth dummy lines L71, L72, L73, and L74 and the first to fourth dummy spaces S71, S72, S73, and S74.

Consequently, the third layout 50″ has the main patterns 51, the dot dummy patterns 61, and the linked line/space dummy patterns 71, 72, 73, and 74. The dot dummy patterns 61 may be formed between the main patterns 51. The dot dummy patterns 61 have relatively lower coupling capacitance. The linked line/space dummy patterns 71, 72, 73, and 74 may be formed between the main patterns 51 and the dot dummy patterns 61. The main patterns 51, the dot dummy patterns 61, and the linked line/space dummy patterns 71, 72, 73, and 74 may have similar pattern densities. Accordingly, the third layout 50″ has an excellent planarization property.

According to the embodiments of the present invention, by only generating the dot dummy patterns 61 and the linked line/space dummy patterns 71, 72, 73, and 74, the third layout 50″ having excellent planarization properties can be obtained. That is, the procedure of designing and making the dummy patterns of the semiconductor device can be simplified.

Hereinafter, methods of designing and making dummy patterns of a semiconductor device according to another embodiment of the present invention will be described with reference to FIG. 9.

Referring to FIG. 9, the same method as that described with reference to FIGS. 2 to 6 is employed to generate the second layout 50′ having the main patterns 51 and the dot dummy patterns 61.

The dot dummy patterns 61 may be disposed arranging rectangular or circular dots in an oblique direction as shown in the drawing. In this case, the dot dummy patterns 61 may be defined as oblique dot dummy patterns. Alternatively, the dot dummy patterns 61 may be formed by arranging rectangular or circular dots in a vertical or horizontal direction. In this case, the dot dummy patterns 61 may be defined as symmetric dot dummy patterns.

The third dummy regions 65 are calculated in the second layout 50′.

While the second layout 50′ is generated, the dot dummy patterns 61′ that at least partially overlap the dummy prohibition regions 55 are eliminated. Accordingly, spaces where the dot dummy patterns 61′ are eliminated occur within the first and second dummy regions 56 and 58. The third dummy regions 65 may be set in the spaces exceeding the resolution limit of the photolithography process among the spaces where the dot dummy patterns 61′ are eliminated. In addition, the third dummy regions 65 may be set to be spaced apart from the main patterns 51 by the first distance D1 and to be spaced apart from the dot dummy patterns 61 by the second distance D2. The first distance D1 and the second distance D2 are preferably set to be higher than the resolution limit of the photolithography process.

As shown in the drawing, the third dummy regions 65 may have bar shapes or linked-bar shapes.

Other dot dummy patterns 91 are added to the third dummy regions 65 to generate a third layout 50″.

Specifically, another dot dummy rule is provided. The other dot dummy patterns 91 may be arranged within the third dummy regions 65 according to the other dot dummy rule. The other dot dummy patterns 91 may use the rectangular or circular dots used for generating the dot dummy patterns 61. In addition, the other dot dummy patterns 91 may be formed by reducing or enlarging the rectangular or circular dots used for generating the dot dummy patterns 61. The other dot dummy rule may provide a minimum size, a maximum size, a minimum interval, a maximum interval, and an arrangement method of the dots. The minimum size and the minimum interval of the dots are preferably set to be higher than the resolution limit of the photolithography process. For example, the other dot dummy patterns 91 may be formed by arranging the rectangular or circular dots which have been used for generating the dot dummy patterns 61 to be spaced apart from each other by the second distance D2. That is, the other dot dummy patterns 91 may be formed by arranging the same rectangular or circular dots as those used for generating the dot dummy patterns 61 to be spaced apart from each other by the second distance D2 within the third dummy regions 65.

Alternatively, the other dot dummy patterns 91 may be arranged within the third dummy regions 65 uniformly spaced apart. That is, the maximum allowable number of dots higher than the resolution limit of the photolithography process is calculated and used to arrange the dots within the third dummy regions 65. The maximum allowable number of dots is arranged uniformly spaced apart within the third dummy regions 65.

The other dot dummy patterns 91 may be material patterns of the same kind as the main patterns 51. That is, the other dot dummy patterns 91 may be conductive patterns or insulating patterns. When the other dot dummy patterns 91 are the conductive patterns, a coupling capacitance may be formed between the other dot dummy patterns 91 and the main patterns 51. In this case, the first distance D1 and the second distance D2 may be set in consideration of electrical characteristics of the other dot dummy patterns 91 and the main patterns 51. In addition, the other dot dummy patterns 91 have the relatively lower coupling capacitance than the plate dummy pattern.

Consequently, the third layout 50″ has the main patterns 51, the dot dummy patterns 61, and the other dot dummy patterns 91. The dot dummy patterns 61 may be generated between the main patterns 51. The other dot dummy patterns 91 may be generated between the main patterns 51 and the dot dummy patterns 61. The dot dummy patterns 61 and the other dot dummy patterns 91 have the relatively lower coupling capacitance. In addition, the main patterns 51, the dot dummy patterns 61, and the other dot dummy patterns 91 may have similar pattern densities. Accordingly, the third layout 50″ has excellent planarization properties.

According to the other embodiment of the present invention, by only generating the dot dummy patterns 61 and the other dot dummy patterns 91 the third layout 50″ having excellent planarization properties can be obtained. That is, the procedure of designing and making the dummy patterns of the semiconductor device can be simplified.

Hereinafter, methods of designing and making dummy patterns of a semiconductor device according to embodiments of the present invention will be described with reference back to FIGS. 7 and 8.

Referring to FIGS. 7 and 8, main patterns 51, dot dummy patterns 61, and linked line/space dummy patterns 71, 72, 73, and 74 are formed on a substrate 81.

The substrate 81 may be a semiconductor substrate such as a silicon wafer. Lower components such as an isolation layer and a transistor can be disposed on the substrate 81, but will be omitted for simplicity of description. A lower interlayer dielectric 83 may be formed on the substrate 81. An upper interlayer dielectric 85 may be formed on the substrate 81 having the lower interlayer dielectric 83. The lower and upper interlayer dielectrics 83 and 85 may be insulating layers such as a silicon oxide layer, a silicon nitride layer, or a silicon oxynitride layer.

The main patterns 51 are disposed within the upper interlayer dielectric 85. The dot dummy patterns 61 are formed between the main patterns 51. In addition, the linked line/space dummy patterns 71, 72, 73, and 74 are formed between the main patterns 51. The main patterns 51 may be conductive patterns or insulating patterns. The dot dummy patterns 61 and the linked line/space dummy patterns 71, 72, 73, and 74 may be material patterns of the same kind as the main patterns 51. That is, the dot dummy patterns 61 and the linked line/space dummy patterns 71, 72, 73, and 74 may also be the conductive patterns or insulating patterns.

The dot dummy patterns 61 may be oblique dot dummy patterns. The oblique dot dummy patterns may be rectangular or circular dots arranged in an oblique direction. The oblique dot dummy patterns may be spaced apart from the main patterns 51 by a first distance D1. The first distance D1 may have a value higher than the resolution limit of a photolithography process. The dots may be spaced apart from one another by a second distance D2. The second distance D2 may have a value higher than the resolution limit of the photolithography process.

The linked line/space dummy patterns 71, 72, 73, and 74 may have links between dummy lines L71, L72, L73, and L74 and dummy spaces. S71, S72, S73, and S74, respectively. The dummy lines L71, L72, L73, and L74 may have bar shapes, elliptical shapes, or combined shapes thereof. The minimum length and width of the dummy lines L71, L72, L73, and L74 may be higher than the resolution limit of the photolithography process. The minimum length and width of the dummy spaces S71, S72, S73, and S74 may also be higher than the resolution limit of the photolithography process. In addition, the linked line/space dummy patterns 71, 72, 73, and 74 may be spaced apart from the main patterns 51 by the first distance D1 and spaced apart from the dot dummy patterns 61 by the second distance D2.

The dot dummy patterns 61 and the linked line/space dummy patterns 71, 72, 73, and 74 may have a pattern density similar to the main patterns 51. When the main patterns 51, the dot dummy patterns 61, and the linked line/space dummy patterns 71, 72, 73, and 74 are formed by a planarization process, the substrate 81 may have a flat top surface.

Hereinafter, methods of fabricating a semiconductor device according to embodiments of the present invention will be described with reference back to FIGS. 7 and 8.

Referring to FIGS. 7 and 8, a lower interlayer dielectric 83 may be formed on a substrate 81.

The substrate 81 may be a semiconductor substrate such as a silicon wafer. Lower components such as an isolation layer and a transistor can be disposed on the substrate 81, but will be omitted for simplicity of description. An upper interlayer dielectric 85 may be formed on the substrate 81 having the lower interlayer dielectric 83. The lower interlayer dielectric 83 may be formed of an insulating layer such as a silicon oxide layer, a silicon nitride layer, or a silicon oxynitride layer by a chemical vapor deposition (CVD) method. The upper interlayer dielectric 85 may be formed of an insulating layer such as a silicon oxide layer by a CVD method. A top surface of the upper interlayer dielectric 85 is preferably planarized. An etch back process or a CMP process may be applied to the planarization.

Trenches may be formed in the upper interlayer dielectric 85. In particular, the third layout 50″ of FIG. 7 may be used to form a photomask. The photomask may be used to form a photoresist pattern on the substrate 81 having the upper interlayer dielectric 85. The upper interlayer dielectric 85 may be anisotropically etched using the photoresist pattern as an etch mask. Consequently, trenches may be formed in the upper interlayer dielectric 85.

A conductive layer may be formed on the substrate 81 having the trenches. The conductive layer may completely fill the trenches and cover the substrate 81. The conductive layer may be formed of a metal layer or a polysilicon layer. The metal layer may be formed of a copper (Cu) layer, a tungsten (W) layer, a titanium (Ti) layer, a titanium nitride (TiN) layer, a tantalum (Ta) layer, a tantalum nitride (TaN) layer, an aluminum (Al) layer, or a combination layer thereof. For example, the metal layer may be formed by sequentially stacking the TiN layer and the Cu layer. In this case, the Cu layer may be formed by an electro plating method, an electroless plating method, or a CVD method.

The conductive layer may be planarized to form main patterns 51, dot dummy patterns 61, and linked line/space dummy patterns 71, 72, 73, and 74 within the trenches. Planarizing the conductive layer may be performed using a CMP process employing the upper interlayer dielectric 85 as a stop layer.

As shown in FIG. 8, by means of the main patterns 51, the dot dummy patterns 61, and the linked line/space dummy patterns L73, S73, and L74, the pattern density of the upper-insulating layer 85 can be equally formed. Accordingly, a top surface of the upper interlayer dielectric 85 can be prevented from being partially recessed while the conductive layer is planarized. That is, top surfaces of the main patterns 51, the dot dummy patterns 61, and the linked line/space dummy patterns L73, S73, and L74 can be substantially formed on the same plane.

The present invention is not limited to the above-described embodiments but may be modified in various other types within the spirit of the present invention. For example, the present invention may be applied to a method of forming a metal interconnection layer, a polysilicon layer, and an active region.

According to the present invention as described above, a first layout having main patterns is provided, dot dummy patterns are added to the first layout to generate a second layout, and linked line/space dummy patterns are added to the second layout to generate a third layout. The dot dummy patterns may be oblique dot dummy patterns. The oblique dot dummy patterns have a relatively lower coupling capacitance than a plate dummy pattern. The linked line/space dummy patterns may be disposed between the main patterns and the dot dummy patterns. The main patterns, the dot dummy patterns, and the linked line/space dummy patterns may have similar pattern densities. Accordingly, the third layout has excellent planarization properties. That is, by only adding the dot dummy patterns and the linked line/space dummy patterns, the third layout having excellent planarization properties can be obtained. Consequently, the design procedure can be simplified and the dummy patterns of the semiconductor device having excellent planarization properties and the low coupling capacitance can be generated.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of making dummy patterns, comprising:
forming a first layout having main patterns;
adding dot dummy patterns to the first layout to generate a second layout; and
adding linked line/space dummy patterns to the second layout to generate a third layout.

2. The method according to claim 1, wherein the dot dummy patterns include oblique dot dummy patterns formed by arranging rectangular or circular dots in an oblique direction.

3. The method according to claim 1, wherein generating the second layout includes:
setting dummy prohibition regions in the first layout;
forming a dummy layout having the dot dummy patterns;
overlaying the dummy layout onto the first layout; and
eliminating dot dummy patterns that at least partially overlap the dummy prohibition regions among the dot dummy patterns of the overlaid dummy layout.

4. The method according to claim 3, wherein the dummy prohibition regions are set by enlarging the main patterns in the first layout by a first distance that is larger than a resolution limit of a photolithography process.

5. The method according to claim 1, wherein the linked line/space dummy patterns are composed of links of dummy lines and dummy spaces, and the dummy line has a bar shape, an elliptical shape, or a combined bar shape and elliptical shape.

6. The method according to claim 1, wherein generating the third layout includes:
determining dummy regions in the second layout;
providing a linked line/space dummy rule; and
generating the linked line/space dummy patterns in the dummy regions of the second layout based on the linked line/space dummy rule.

7. The method according to claim 6, wherein the dummy regions are spaced apart from the main patterns by a first distance and spaced apart from the dot dummy patterns by a second distance, the first and second distances having values higher than a resolution limit of a photolithography process.

8. The method according to claim 6, wherein the linked line/space dummy rule includes a dummy line rule and a dummy space rule.

9. The method according to claim 8, wherein the dummy line rule includes a minimum length, a minimum width, a maximum length, and a maximum width of a dummy line, and the minimum length and the minimum width of the dummy line have values higher than a resolution limit of a photolithography process.

10. The method according to claim 8, wherein the dummy space rule includes a minimum length, a minimum width, a maximum length, and a maximum width of a dummy space, and the minimum length and the minimum width of the dummy space have values higher than a resolution limit of a photolithography process.

11. A method of making dummy patterns, comprising:
forming a first layout having main patterns;
adding dot dummy patterns to the first layout to generate a second layout, the dot dummy patterns having rectangular or circular dots;
determining dummy regions in the second layout; and
adding the dots to the dummy regions of the second layout such that an inter-dot spacing is larger than a resolution limit of a photography process to generate a third layout.

12. The method according to claim 11, wherein the dot dummy patterns include oblique dot dummy patterns formed by arranging the rectangular or circular dots in an oblique direction.

13. The method according to claim 11, wherein generating the second layout includes:
setting dummy prohibition regions in the first layout;
forming a dummy layout having the dot dummy patterns;
overlaying the dummy layout onto the first layout; and
eliminating dot dummy patterns that at least partially overlap the dummy prohibition regions among the dot dummy patterns of the overlaid dummy layout.

14. The method according to claim 13, wherein the dummy prohibition regions are set by enlarging the main patterns in the first layout by a first distance that is larger than a resolution limit of a photolithography process.

15. The method according to claim 11, wherein the dummy regions are spaced apart from the main patterns by a first distance and spaced apart from the dot dummy patterns by a second distance, the first and second distances having values higher than a resolution limit of a photolithography process.

16. A semiconductor device, comprising:
a substrate;
main patterns formed on the substrate;
dot dummy patterns disposed between the main patterns on the substrate; and
linked line/space dummy patterns disposed between the main patterns on the substrate.

17. The semiconductor device according to claim 16, wherein the dot dummy patterns include oblique dot dummy patterns formed by arranging rectangular or circular dots in an oblique direction.

18. The semiconductor device according to claim 17, wherein the oblique dot dummy patterns are spaced apart from the main patterns by a first distance having a value higher than a resolution limit of a photolithography process.

19. The semiconductor device according to claim 17, wherein the dots are spaced apart from one another by a second distance having a value higher than a resolution limit of a photolithography process.

20. The semiconductor device according to claim 16, wherein the linked line/space dummy patterns include links of dummy lines and dummy spaces, and the dummy line has a bar shape, an elliptical shape, or a combined bar shape and elliptical shape.

21. The semiconductor device according to claim 16, wherein the linked line/space dummy patterns are spaced apart from the main patterns by a first distance and spaced apart from the dot dummy patterns by a second distance, the first and second distances having values higher than a resolution limit of a photolithography process.
